(19) United States
(12) Patent Application Publication
(10) Pub. No.: US 2026/0018816 A1
(43) Pub. Date: Jan. 15, 2026

(54) EDGE CARD CONNECTOR WITH PROBE-ACCESS APERTURES

(71) Applicant: Aivres Systems Inc., San Jose, CA (US)

(72) Inventor: Yi-An CHEN, New Taipei City (TW)

(21) Appl. No.: 19/338,376

(22) Filed: Sep. 24, 2025

(51) Int. Cl. H01R 12/73; G01R 1/04; H01R 13/52

(52) U.S. Cl. CPC H01R 12/737; G01R 1/0416; H01R 13/5213

(57) ABSTRACT

An edge-card connector mounted to a PCB includes a housing that retains contact terminals arranged in differential pairs for mating via a card-mating slot. The housing further defines, on an exterior face distinct from the slot, probe-access aperture sets aligned to the differential pairs. Each set has two apertures with spacing and orientation registered to the pair and sized to receive probe tips, guiding the tips into contact with corresponding terminals while preventing contact with neighboring terminals to enable in-situ measurement.

### TECHNICAL FIELD

This disclosure relates to electrical edge-card connectors for high-speed serial interfaces, e.g., Peripheral Component Interconnect Express (PCIe) connectors, and to structures that provide guided probe access to differential signal pairs for in-situ electrical measurement.

### BACKGROUND

Modern server platforms, including those aligned with OCP and DC-MHS, rely on high-speed serial interconnects implemented as differential signal pairs in edge-card connectors. During bring-up, validation, failure analysis, and manufacturing diagnostics, engineers need to measure lane performance on the actual terminals under real operating conditions. Small variations in layout or process can materially affect eye quality, margin, and negotiated link speed, so stable, repeatable access to the true differential terminals is important.

In current practice, measurements are commonly performed using custom test cards designed for a given end product. These test cards break out selected lanes for probing, but they introduce non-idealities and consume significant time and cross-functional effort to design, route, fabricate, and assemble. They also become obsolete when connector pin assignments change between product generations, leading to recurring delay, cost, and waste.

Directly probing the connector's tightly spaced metal terminals without a test card is risky. The pitch is dense, neighboring high-speed and power pins are adjacent, and surrounding components limit access, so probe tips can slip or bridge pins, causing shorts or damage. Ad-hoc access lacks guidance, depth control, and insulation from adjacent terminals, making repeatable measurements difficult, particularly when the card must remain inserted to establish a true operational link.

Accordingly, there is a need for connector-level structures that provide guided, insulated, geometry-registered access to the actual differential terminals so engineers can perform in-situ measurements with the add-in card seated, while avoiding the delay, cost, and resource waste associated with designing and discarding custom test cards.

### SUMMARY

A system of one or more computers can be configured to perform particular operations or actions by virtue of having software, firmware, hardware, or a combination of them installed on the system that, in operation, cause the system to perform the actions. One or more computer programs can be configured to perform particular operations or actions by virtue of including instructions that, when executed by a data processing apparatus, cause the apparatus to perform the actions.

In one general aspect, an edge-card connector mounted to a printed circuit board (PCB) includes a housing that supports conductive contact terminals arranged in differential signal pairs for mating with an edge card through a card-mating slot. The housing also forms, on an exterior face distinct from the card-mating slot, multiple probe-access aperture sets that each correspond to a respective differential signal pair. Each aperture set has two apertures whose center-to-center spacing and orientation are registered to the geometry of the corresponding pair and are sized to receive the respective tips of a probe. In use, the apertures guide the probe tips into contact with the intended terminals while preventing contact with neighboring terminals, enabling in-situ electrical measurements on the actual connector terminals.

In some embodiments the aperture sets are provided on opposed exterior side faces of the housing so a user can probe from either side of the connector. For at least one differential signal pair, mirror-oriented aperture sets can be aligned to the same pair on opposite faces. Within each set, the two apertures may be placed at different heights relative to the PCB to create a staggered pattern registered to the pair, which can improve approach clearance for the two probe tips. In other embodiments the two apertures within each set are at the same height, while adjacent sets are positioned at different heights along the connector; selecting these different heights increases tool clearance from set to set and reduces accidental contact during probing.

Additional structural features can be included to improve guidance and insulation. Each aperture may incorporate a depth-limiting structure that constrains probe insertion so the tip reaches the intended contact region without over-travel. A dielectric bushing or liner can be provided within each aperture to center the received probe tip, define a minimum lateral clearance to adjacent terminals, and electrically insulate the tip along a length of insertion. In some versions each aperture extends from an exterior-side opening at a first, greater height above the PCB to an interior-side opening at a second, lower height proximate the corresponding terminal, establishing a guided, oblique approach path. The center-to-center spacing of the two apertures in a set may match, within a mechanical tolerance, the spacing of the terminals of the corresponding differential pair to promote repeatable measurements.

Optional operational features can enhance usability and protection. A probe-retention mechanism associated with each aperture can hold a probe tip in contact with the terminal without continuous manual force. The housing may include a removable cover movable between closed and open positions, an integral barrier wall liftable to expose the apertures, or individual spring-loaded shutters that bias closed and open upon probe insertion to resist dust ingress. Collectively, these structures provide safe, repeatable, and scalable access to differential terminals for compliance and diagnostics while a card is seated in the connector.

### BRIEF DESCRIPTION OF THE DRAWINGS

The subject matter disclosed provides connector-level structures that enable safe, repeatable, in-situ measurement of high-speed differential signals on the actual terminals of an edge-card connector. By forming guided probe-access apertures in the connector housing (rather than relying on external test cards or risky hand probing), the approaches reduce short-circuit risk, avoid channel artifacts introduced by breakout fixtures, and scale across products and lane counts with minimal rework.

FIG. 1A illustrates an example edge-card connector on a printed circuit board (PCB), in accordance with some embodiments.

FIG. 1B illustrates an example connector and hardware layout on a PCB, in accordance with some embodiments.

FIG. 2 illustrates an example test card for measuring differential signal pairs, in accordance with some embodiments.

FIG. 3 illustrates an example edge-card connector with guided probe-access apertures, in accordance with some embodiments.

FIG. 4 illustrates an example location for the guided probe-access apertures on the edge-card connector, in accordance with some embodiments.

FIG. 5 illustrates an example cross-sectional view of an edge-card connector with guided probe-access apertures, in accordance with some embodiments.

FIG. 6A illustrates example placements of the guided probe-access apertures on the edge-card connector, in accordance with some embodiments.

FIG. 6B illustrates other example features of the guided probe-access apertures on the edge-card connector, in accordance with some embodiments.

### DETAILED DESCRIPTION OF EMBODIMENTS

In the following description, certain specific details are set forth in order to provide a thorough understanding of various embodiments of the disclosure. However, one skilled in the art will understand that the disclosure may be practiced without these details. Moreover, while various embodiments of the disclosure are disclosed herein, many adaptations and modifications may be made within the scope of the disclosure in accordance with the common general knowledge of those skilled in this art. Such modifications include the substitution of known equivalents for any aspect of the disclosure in order to achieve the same result in substantially the same way.

Unless the context requires otherwise, throughout the present specification and claims, the word “comprise” and variations thereof, such as, “comprises” and “comprising” are to be construed in an open, inclusive sense, that is as “including, but not limited to.” Recitation of numeric ranges of values throughout the specification is intended to serve as a shorthand notation of referring individually to each separate value falling within the range inclusive of the values defining the range, and each separate value is incorporated in the specification as it were individually recited herein. Additionally, the singular forms “a,” “an” and “the” include plural referents unless the context clearly dictates otherwise.

Reference throughout this specification to “one embodiment” or “an embodiment” means that a particular feature, structure or characteristic described in connection with the embodiment is included in at least one embodiment of the present disclosure. Thus, the appearances of the phrases “in one embodiment” or “in an embodiment” in various places throughout this specification are not necessarily all referring to the same embodiment, but may be in some instances. Furthermore, the particular features, structures, or characteristics may be combined in any suitable manner in one or more embodiments.

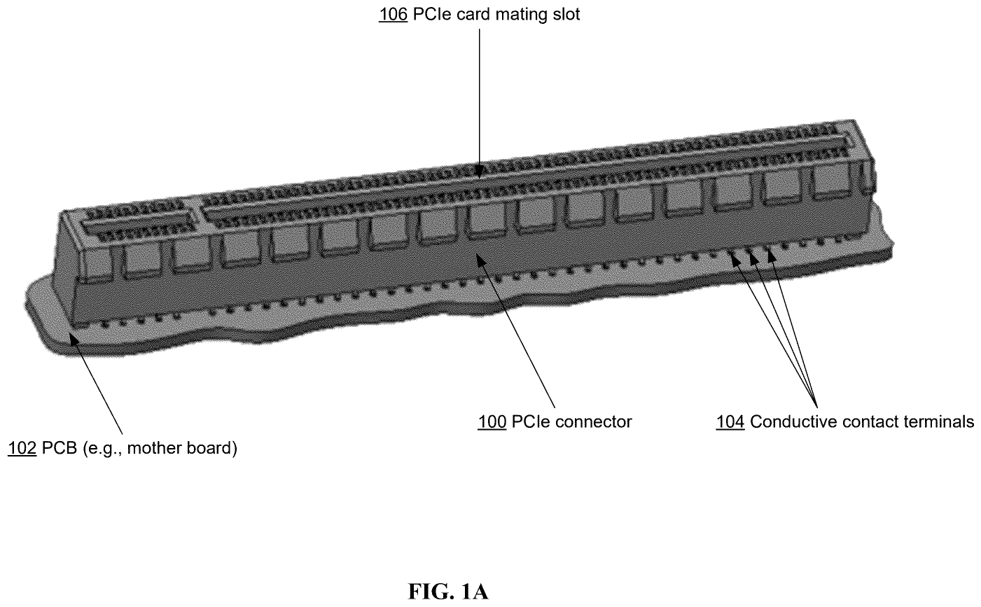

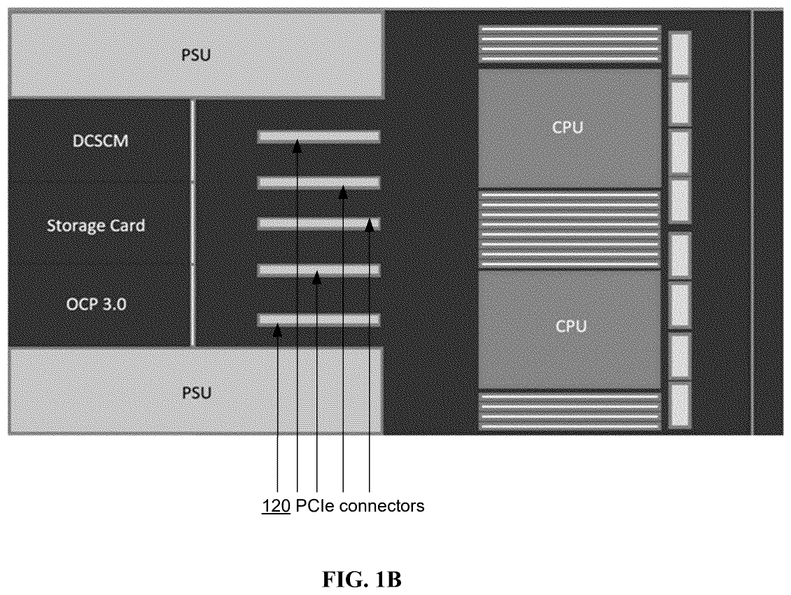

FIG. 1A illustrates an example edge-card connector on a printed circuit board (PCB), in accordance with some embodiments. As shown, the connector is a PCIe connector 100, which includes a molded insulating body that defines a card-mating slot 106 sized to receive an add-in PCIe card's conductive edge fingers (also called gold fingers). Along the card-mating slot 106, the PCIe connector 100 retains a plurality of metal conductive contact terminals 104. Each terminal 104 has a mating portion exposed in the PCIe slot 106 to engage the PCIe card's conductive edge fingers and a PCB-termination portion (e.g., surface-mount, through-hole, or press-fit) coupled to pads or plated holes on the PCB 102. The conductive contact terminals 104 are laid out in differential pairs to carry high-speed serial lanes in accordance with PCIe signaling, with additional terminals assigned to power and sideband functions. In typical implementations the number of pairs scales with lane width (for example, x1, x4, x8, x16), and the physical pitch between adjacent terminals is tight to preserve controlled impedance and compact board real estate.

This conventional geometry explains why measuring lane performance at the connector is both valuable and challenging. Link speed and signal integrity depend on the end-to-end channel that includes the add-in card, the mating interface at the card-mating slot 106, the PCIe connector 100, and the PCB 102 routing and vias. The contact terminals 104 are arranged in differential signal pairs, in which each pair comprises a positive conductor (P) and a negative conductor (N) carrying equal-and-opposite waveforms; receivers sense the difference between P and N to reject common-mode noise and enable higher data rates. Because PCIe lanes are specified and tested as differential pairs, measurement and compliance verification are performed on the P/N pair rather than on a single terminal in isolation.

Compliance and margin checks are most informative when taken on the true P/N terminals (e.g., a pair of neighboring conductive contact terminals 104) with the link trained and operating. However, the tight terminal pitch, proximity of neighboring high-speed and power pins, and nearby components make it risky to bring probe tips directly into the connector region; probes can slip, bridge pins, or contact unintended metal.

Later figures introduce guided probe-access structures formed in the connector housing that support conductive contact terminals so an engineer can perform simplified, in-situ speed and integrity testing at the terminals 104 with an add-in card seated in the slot 106, without resorting to bespoke breakout test cards. Here, a “housing that supports” means that the housing of the PCIe connector 100 physically retains and positions the plurality of metal contact terminals 104 within the connector body.

FIG. 1B illustrates an example connector and hardware layout on a PCB, in accordance with some embodiments. In this representative server board, a row of PCIe connectors 120 is placed between platform management and storage modules on the left and processor subsystems on the right. The left column shows, for example, a DC-SCM module, a storage card, and an OCP 3.0 module, while power supply units (PSU) occupy chassis regions at the top and bottom. On the right, CPU packages with associated subsystems are depicted; adjacent real estate is typically populated with dense components such as memory modules, VRMs, and heat-sink hardware. This context highlights that the area around each connector 120 is space-constrained and governed by keep-outs for airflow, thermals, and high-speed routing, making direct access to tightly pitched conductive contact terminals 104 difficult during bring-up and manufacturing test.

In current practice, engineers often rely on a purpose-built test card inserted into a selected connector 120 to evaluate supported PCIe link speeds or to expose signals for measurement when endpoint coverage through BIOS is insufficient. While workable for a few experiments, the test-card approach does not scale across a board populated with many connectors. Each board spin may change lane mappings, widths, or connector families, forcing new test-card designs that consume layout, fabrication, and validation cycles, only to be discarded after a short use.

More importantly, test cards also occupy the connector under test, preventing measurements with the actual add-in card installed and potentially altering the channel with added stubs and return-path changes. As program counts and lane counts grow, the cumulative delay, engineering cost, and waste associated with designing, building, and handling multiple test cards become significant.

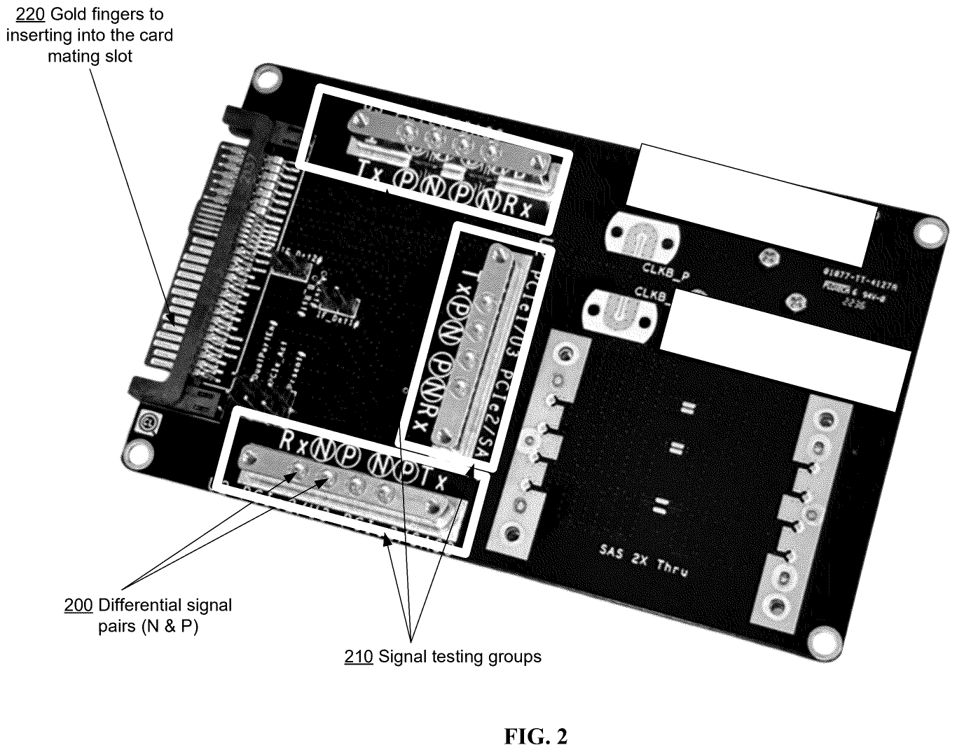

FIG. 2 illustrates an example test card configured to measure PCIe differential signal pairs 200 (N & P), in accordance with some embodiments. The card includes gold fingers 220 that insert into the connector's card-mating slot so the test card electrically mates with the host connector for testing. Each PCIe lane is implemented as a differential pair comprising a positive conductor (P) and a negative conductor (N). PCIe links are bidirectional: the host board presents Tx (Transmit) pairs that drive toward the add-in card and Rx (Receive) pairs that receive from the add-in card. In example connector implementations, Rx and Tx pairs are distributed on opposing rows/sides of the edge-card interface, so accessing both directions usually requires separate breakout features.

This example test card provides three signal testing groups 210. Each signal testing group 210 breaks out one Rx P/N pair and the corresponding Tx P/N pair of a selected lane to accessible measurement points, allowing an oscilloscope's differential probe to contact those pairs while the card is inserted. Because the breakout is hard-wired, the card can expose only a fixed subset of lanes (here, three lanes per direction) leaving the remaining many pairs of the host connector untested. Consequently, a single card cannot cover all conductive contact terminals of a multi-lane connector (e.g., x8 or x16), and new cards must be designed when a different set of lanes or a different pin map needs to be measured.

Moreover, this approach requires the test card itself to occupy the mating slot of the connector during measurement, which prevents testing with the actual PCIe add-in card to be installed. As a result, while workable for limited bring-up tasks, the test-card solution is not scalable across boards populated with many connectors and lanes, and it introduces schedule and cost penalties that motivate the guided probe-access structures described in later figures.

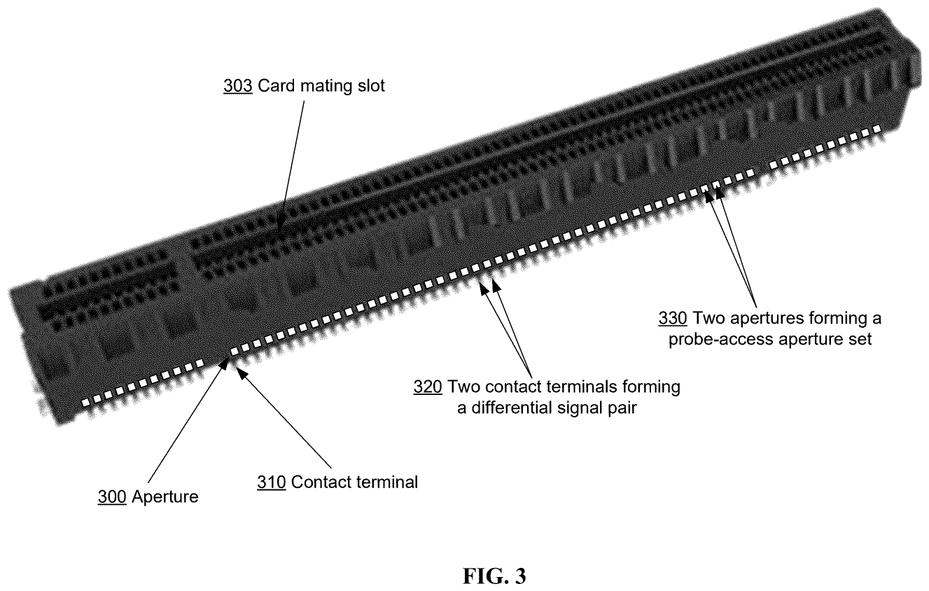

FIG. 3 illustrates an example edge-card connector in which the connector housing defines guided probe-access features opening at an exterior face distinct from the card-mating slot 303 and extending through the housing toward an interior opening to access the contact terminals, in accordance with some embodiments. In this specification, the term “exterior face” is also referred to as the outer side face of the connector housing that is distinct from the card-mating slot opening and from the board-mounting face that contacts the PCB. As shown, along the card-mating slot 303, the connector housing (i.e., the body) supports a plurality of conductive contact terminals 310. The terminals are arranged as two contact terminals forming a differential signal pair 320 (P and N conductors of a PCIe lane), with additional terminals (e.g., power and sideband) omitted for clarity.

On the exterior side face of the housing, the connector defines multiple small apertures 300. For each differential pair 320 of conductive contact terminals, two apertures 300 are positioned as a probe-access aperture set 330. In some embodiments, each probe-access aperture set 330 may be located, sized, and oriented so that its two apertures have a center-to-center spacing and angular registration that correspond to the spacing and orientation of the two contact terminals 310 of the associated pair 320 within a mechanical tolerance. As used herein, “center-to-center spacing” means the distance between the geometric centers of the two apertures measured parallel to the row of terminals (i.e., in the plane of the exterior face). The apertures need not be collinear with the terminals: in some embodiments the two apertures are at the same height, and in other embodiments one aperture is higher than the other. “Registration” means that each aperture is paired with its corresponding terminal so that the internal passage guides the probe tip to that terminal. In other embodiments, the apertures of a set 330 are vertically or laterally offset (e.g., at different heights or along an oblique path) to improve tool clearance, while the internal passage geometry still guides the probe tips toward the intended terminals 310 of the pair 320. The apertures 300 are dimensioned to receive respective tips of a test probe and to guide the tips along a controlled approach path toward the intended contact regions of the terminals 310 while maintaining insulating separation from neighboring terminals.

In some embodiments, each aperture 300 includes a depth-limiting structure (such as a shoulder, narrowed section, or stop ridge) that constrains insertion so the probe tip reaches the contact region of the intended terminal 310 without over-travel. In some embodiments, a dielectric bushing or liner within each aperture 300 centers an inserted probe tip, defines a minimum lateral clearance to adjacent terminals, and electrically insulates the tip from neighboring conductive contact terminals along a length of insertion.

By providing the plurality of probe-access aperture sets 330 for the plurality of differential pairs 320 and configuring the apertures 300 to guide probe tips toward the corresponding terminals 310, the connector housing enables repeatable, in-situ measurements taken on the actual P/N terminals while an add-in card is seated in the slot 303, while reducing the risk of unintended contact with neighboring terminals.

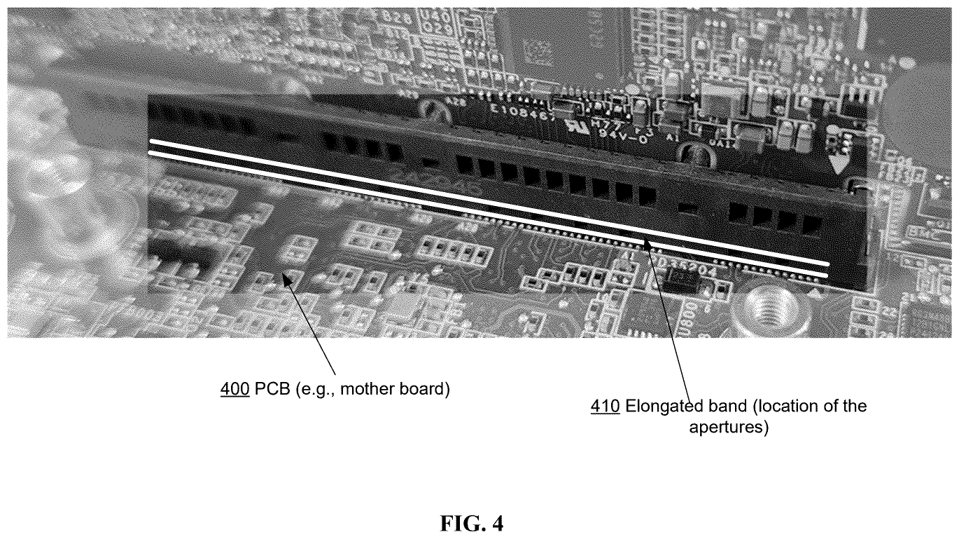

FIG. 4 illustrates an example location for the guided probe-access apertures on the edge-card connector, in accordance with some embodiments. The figure shows the connector mounted to the PCB 400, with the proposed aperture region indicated by the elongated band 410 along the lower, exterior side face of the housing adjacent the PCB 400.

Positioning the apertures at the elongated band 410 (i.e., the lower band) of the exterior side face near the board side places the probe entry close to the PCB-termination portions of the conductive contact terminals inside the housing. This shortens the mechanical and electrical approach path to the target terminals, reduces loop area and stray inductance for differential measurements, improves shielding from the nearby ground planes and reference conductors in the PCB 400, and avoids interference with latching features and card insertion dynamics at the upper card-mating slot. Locating the apertures low on the side wall also keeps the probe work envelope below heat sinks and airflow channels that typically crowd the upper region of the connector.

In some embodiments, the apertures in the elongated band 410 are arranged as probe-access aperture sets on one or both exterior side faces of the housing, with each probe-access aperture set aligned to a corresponding differential pair of conductive contact terminals as described above. The passages can be straight (the passage extends along a substantially linear axis (not curved or bent) through the thickness of the housing) or oblique (the linear axis of the passage is angled relative to a normal line perpendicular to the PCB plane, such that if extended, it would intersect the PCB plane at a non-perpendicular angle) toward the target terminals, and the exterior openings may be at a higher height than the interior openings (with respect to the PCB) to guide the probe tips downward toward the terminal regions. The apertures can be formed as part of the housing molding using side-action cores or inserts, or created by a post-mold secondary process such as laser drilling or precision machining.

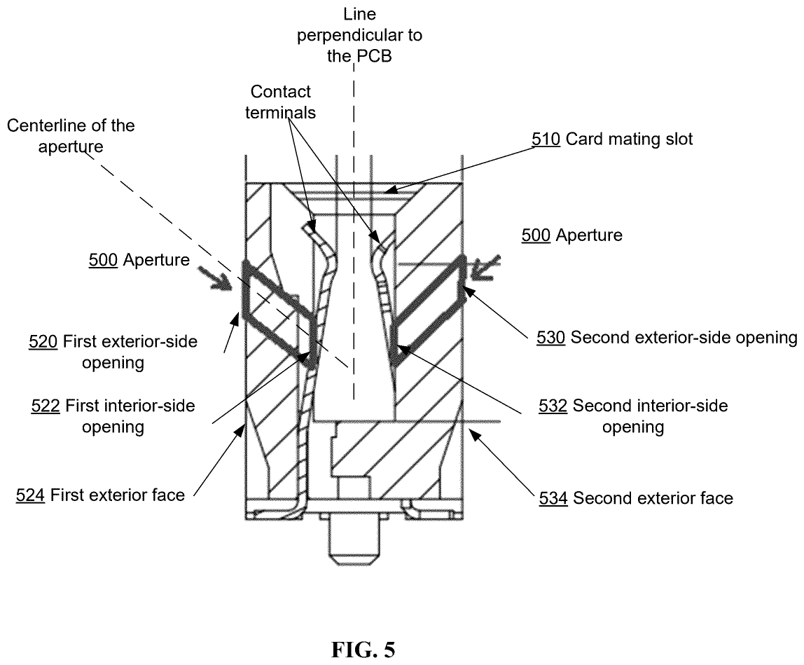

FIG. 5 illustrates an example cross-sectional view of an edge-card connector with guided probe-access apertures, in accordance with some embodiments. In cross-sectional view, the connector housing defines a card-mating slot 510 and presents two opposed exterior side faces (a first exterior face 524 and a second exterior face 534), each located on a side of the housing distinct from the card-mating slot 510 and oriented substantially perpendicular to the PCB (not shown in FIG. 5, which is a horizontal plane to which the connector will be mounted).

On the first exterior face 524, an aperture 500 extends through the housing from a first exterior-side opening 520 at a first height above the PCB to a first interior-side opening 522 at a lower height proximate the intended contact-terminal region inside the housing. On the opposite exterior face 534, a corresponding aperture 500 extends from a second exterior-side opening 530 at a greater height to a second interior-side opening 532 at a lower height. The difference in heights between each exterior-side opening (520, 530) and its corresponding interior-side opening (522, 532) establishes an oblique, guided approach path toward the target terminal regions, while keeping the exterior openings low on the side wall to maximize clearance from latches, heat sinks, airflow channels, and other features near the slot 510. In some embodiments, the centerline of each aperture is angled relative to a line perpendicular to the PCB, such that the angled orientation guides the probe tip directly toward the corresponding conductive contact terminal.

In some embodiments, each exterior side face (524, 534) may carry probe-access aperture sets formed by two apertures 500 arranged as a pair and registered to a corresponding differential signal pair; only one aperture is visible per side in this sectional view. In further embodiments, mirror-oriented aperture sets are provided on both exterior faces for the same differential pair so that a technician can probe from either side of the connector.

Dual-side access improves serviceability in densely populated systems where components or chassis walls block one side, allows probe routing to follow the shortest, least-strained path, and enables simultaneous use of left-hand and right-hand probe fixtures. Providing opposed faces also lets the internal passages be tailored to local constraints (for example, selecting different approach angles on the two sides to avoid nearby components), while still guiding the probe tips to the intended terminal regions. Optional internal details, such as molded depth-limiting shoulders and dielectric liners within the apertures 500, can center the probe tips, control insertion depth, and maintain insulating clearance to neighboring terminals along the length of insertion.

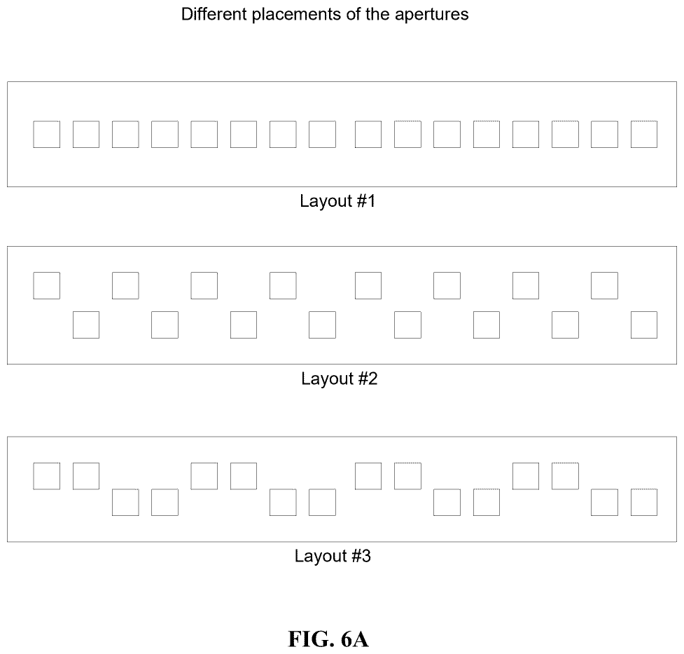

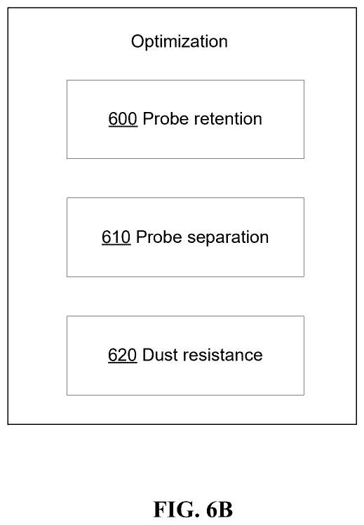

FIG. 6A illustrates example placements of the guided probe-access apertures on the edge-card connector, in accordance with some embodiments.

In a first embodiment (Layout #1), all apertures are located at a same height relative to the PCB. This uniform row simplifies molding or machining, cases visual alignment, and works well with fixtures that dock multiple probes at a single datum height. It also preserves maximum wall thickness above and below the apertures, which can improve housing stiffness and provide room for liners or depth stops.

In a second embodiment (Layout #2), the two apertures within each probe-access aperture set are at different heights to form a staggered pattern registered to the corresponding differential signal pair. Staggering within each probe-access aperture set increases the lateral and vertical clearance between the two incoming probe tips, reducing the chance that tips or ferrules collide or scrape the housing during insertion. The oblique approach paths (shown in FIG. 5) can be tuned so each tip enters with a different angle or depth stop, which helps avoid interference from nearby components on the PCB side while still guiding the tips to the intended P/N terminals. The vertical offset can also improve insulation spacing and reduce accidental bridging when hands or fixtures are moved during measurement.

In a third embodiment (Layout #3), the two apertures of each probe-access aperture set are at the same height, but adjacent probe-access aperture sets are positioned at different heights along the connector. The vertical offsets between neighboring probe-access aperture sets may be selected with the geometry of typical differential probes in mind (e.g., probe body diameter, ferrule length, strain-relief boot size, and minimum cable bend radius) so that when a user brings a probe into one set there is physical clearance from the next set. This step-wise arrangement reduces crowding of probe tips, barrels, and cables, lowers the chance that a tip or sleeve brushes an adjacent opening or exposed metal, and thereby reduces accidental contact during probing. The alternating heights also create small ledges between sets that help the operator's hand “index” to the intended target and resist lateral slipping across multiple openings, which is especially useful when working around heat sinks, card latches, or other obstructions. In fixtures that hold multiple probes, the offset pattern provides interleaved routing paths that prevent cables from stacking on a single plane, further improving tool clearance and repeatability during lane-to-lane measurements.

Across these embodiments, the placement strategy can be selected to balance manufacturability, mechanical robustness, and measurement fidelity. Uniform rows favor simple tooling and automated probe fixtures; within-set staggering prioritizes safe insertion and insulation between the two tips of a pair; alternating heights between adjacent sets enhances accessibility in dense layouts. In all cases, the aperture location and internal passage geometry are registered to the target differential pair so that probe tips are guided toward the intended contact regions while maintaining insulating separation from neighboring terminals.

FIG. 6B illustrates additional optimizations that may be incorporated into the guided probe-access structure, including probe retention 600, probe separation 610, and dust resistance 620, in accordance with some embodiments.

In some embodiments, a probe-retention feature 600 (e.g., a probe-retention clip, liner, or sleeve) is associated with each aperture of a probe-access aperture set. The probe-retention feature may be provided by an internal detent or shoulder that the probe ferrule seats against, an elastomeric bushing or compliant liner formed of an electrically insulating material, the bushing or liner defining a cylindrical or keyed opening concentric with the aperture axis and having a tapered lead-in, and the bushing or liner applying friction around the inserted probe tip These structures hold the probe tip in stable contact with the intended conductive contact terminal without continuous manual force, reduce motion-induced jitter in the measured waveform, and free the operator's hands for calibration and equipment adjustment.

The probe separation feature 610 enhances electrical and mechanical isolation during insertion and measurement. In some embodiments, each aperture includes a dielectric bushing or liner that centers the received probe tip and defines a minimum lateral clearance to neighboring conductive contact terminals along a length of insertion. In other embodiments, the housing forms barrier portions between the aperture and non-target terminals, and the internal passage is shaped to guide the probe along an oblique approach that avoids adjacent metal. In some embodiments, the connector housing defines an internal barrier portion that is laterally interposed between an aperture of a probe-access aperture set and conductive contact terminals that are not members of the corresponding differential signal pair, thereby maintaining insulating separation and reducing the risk of unintended contact. These measures maintain insulating spacing, mitigate accidental bridging, and improve repeatability when probing tightly pitched differential signal pairs.

The dust-resistance feature 620 protects unused apertures and the interior of the connector housing from particulate ingress. In some embodiments, an integral barrier wall is positioned above a row of probe-access aperture sets and is liftable between a closed position covering the sets and an open position exposing them for measurement. In other embodiments, a removable cover slides on a rail of the housing to selectively expose the apertures, or individual spring-loaded shutters bias closed over each aperture and are displaced open by insertion of a probe tip. These closures can be molded as part of the housing or formed as separate components, and may be combined with seals or liners to further limit contamination while preserving the guided insertion geometry described above.

The various features and processes described above may be used independently of one another or may be combined in various ways. All possible combinations and sub-combinations are intended to fall within the scope of this disclosure. In addition, certain method or process blocks may be omitted in some implementations. The methods and processes described herein are also not limited to any particular sequence, and the blocks or states relating thereto can be performed in other sequences that are appropriate. For example, described blocks or states may be performed in an order other than that specifically disclosed, or multiple blocks or states may be combined in a single block or state. The example blocks or states may be performed in serial, in parallel, or in some other manner. Blocks or states may be added to or removed from the disclosed example embodiments. The exemplary systems and components described herein may be configured differently than described. For example, elements may be added to, removed from, or rearranged compared to the disclosed example embodiments.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Although an overview of the subject matter has been described with reference to specific example embodiments, various modifications and changes may be made to these embodiments without departing from the broader scope of embodiments of the present disclosure. Such embodiments of the subject matter may be referred to herein, individually or collectively, by the term “invention” merely for convenience and without intending to voluntarily limit the scope of this application to any single disclosure or concept if more than one is, in fact, disclosed.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

Any process descriptions, elements, or blocks in the flow diagrams described herein and/or depicted in the attached figures should be understood as potentially representing modules, segments, or portions of code which include one or more executable instructions for implementing specific logical functions or steps in the process. Alternate implementations are included within the scope of the embodiments described herein in which elements or functions may be deleted, executed out of order from that shown or discussed, including substantially concurrently or in reverse order, depending on the functionality involved, as would be understood by those skilled in the art.

As used herein, “or” is inclusive and not exclusive, unless expressly indicated otherwise or indicated otherwise by context. Therefore, herein, “A, B, or C” means “A, B, C, A and B, A and C, B and C, or A, B, and C,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context. Moreover, plural instances may be provided for resources, operations, or structures described herein as a single instance. Additionally, boundaries between various resources, operations, engines, and data stores are somewhat arbitrary, and particular operations are illustrated in a context of specific illustrative configurations. Other allocations of functionality are envisioned and may fall within a scope of various embodiments of the present disclosure. In general, structures and functionality presented as separate resources in the example configurations may be implemented as a combined structure or resource. Similarly, structures and functionality presented as a single resource may be implemented as separate resources. These and other variations, modifications, additions, and improvements fall within a scope of embodiments of the present disclosure as represented by the appended claims. The specification and drawings are, accordingly, to be regarded in an illustrative rather than a restrictive sense.

The term “include” or “comprise” is used to indicate the existence of the subsequently declared features, but it does not exclude the addition of other features. Conditional language, such as, among others, “can,” “could,” “might,” or “may,” unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without user input or prompting, whether these features, elements and/or steps are included or are to be performed in any particular embodiment.

What is claimed is:

1. An edge card connector mounted to a printed circuit board (PCB), the connector comprising:
a housing supporting a plurality of conductive contact terminals arranged in differential signal pairs for mating with an edge card through a card-mating slot,
the housing defining, on an exterior face distinct from the card-mating slot, a plurality of probe-access aperture sets respectively corresponding to the differential signal pairs, each of the plurality of probe-access aperture sets comprising two apertures having a center-to-center spacing and orientation registered to the corresponding differential signal pair and sized to receive respective tips of a probe, and
each of the plurality of probe-access aperture sets being configured to guide the tips of the probe into contact with the conductive contact terminals of the corresponding differential signal pair while preventing the tips of the probe from contacting neighboring conductive contact terminals.

2. The connector of claim 1, wherein the plurality of probe-access aperture sets are located on two opposed exterior side faces of the housing, each side face being distinct from the card-mating slot.

3. The connector of claim 1, wherein the two apertures within each probe-access aperture set are at different heights relative to the PCB to form a staggered pattern registered to the corresponding differential signal pair.

4. The connector of claim 1, wherein the two apertures within each probe-access aperture set are at a same height relative to the PCB, and
wherein two probe-access aperture sets corresponding to adjacent differential signal pairs are at different heights relative to the PCB.

5. The connector of claim 1, wherein each of the two apertures comprises a depth-limiting structure that constrains insertion of a tip of the probe to prevent contact with conductive contact terminals other than the conductive contact terminal corresponding to the aperture.

6. The connector of claim 1, wherein each aperture of each probe-access aperture set comprises a dielectric bushing or liner that defines a minimum lateral clearance between a received tip of the probe and neighboring conductive contact terminals.

7. The connector of claim 1, wherein the housing comprises an integral barrier wall positioned above the plurality of probe-access aperture sets, the barrier wall being liftable between a closed position covering the plurality of probe-access aperture sets and an open position exposing the plurality of probe-access aperture sets, to resist dust ingress.

8. The connector of claim 1, wherein each probe-access aperture set extends through the housing from an exterior-side opening at a first height above the PCB to an interior-side opening at a second height above the PCB, wherein the interior-side opening is proximate the corresponding conductive contact terminal, and the first height is greater than the second height.

9. The connector of claim 1, wherein the center-to-center spacing of the apertures of each probe-access aperture set matches a center-to-center spacing of the conductive contact terminals of the corresponding differential signal pair within a mechanical tolerance.

10. The connector of claim 1, further comprising:
a probe-retention clip associated with each aperture, the probe-retention clip being configured to hold a tip of the probe in contact with the conductive contact terminal without continuous manual force.

11. The connector of claim 1, further comprising:
a removable cover on the housing between a closed position covering the plurality of probe-access aperture sets and an open position exposing the plurality of probe-access aperture sets.

12. The connector of claim 1, further comprising:
a plurality of spring-loaded shutters, each spring-loaded shutter biasing closed over a respective aperture of each probe-access aperture set and being displaced open by insertion of a tip of the probe.

13. The connector of claim 2, wherein the housing defines, for at least one differential signal pair, two opposed probe-access aperture sets aligned to the same differential signal pair on opposite exterior faces.

14. The connector of claim 6, wherein the dielectric bushing or liner is configured to center a tip of the probe and electrically insulate the tip of the probe from neighboring conductive contact terminals along a length of insertion.

15. The connector of claim 4, wherein the different heights of the plurality of probe-access aperture sets corresponding to adjacent differential signal pairs are selected to increase tool clearance and reduce accidental contact during probing.

16. The connector of claim 1, wherein at least one exterior side face of the housing that carries the plurality of probe-access aperture sets is oriented substantially perpendicular to the PCB.

17. The connector of claim 1, wherein the plurality of probe-access aperture sets are disposed in a lower band of the exterior side face proximate the PCB.

18. The connector of claim 8, wherein a centerline of each aperture is angled relative to a line perpendicular to the PCB to guide the probe toward the corresponding conductive contact terminal.

19. The connector of claim 1, wherein the housing further comprises:
an internal barrier portion laterally interposed between an aperture of a probe-access aperture set and conductive contact terminals that are not members of the corresponding differential signal pair.

20. The connector of claim 10, wherein the probe-retention clip comprises a keyed sleeve configured to mate with the probe to resist withdrawal while maintaining tip contact with the conductive contact terminal.
